(19) United States
(12) Patent Application Publication
(10) Pub. No.: US 2004/0053509 A1
(43) Pub. Date: Mar. 18, 2004

(54) Fluid treatment system

(76) Inventors: Wataru Okase, Tsukui-gun (JP); Jun Yamauchi, Tsukui-gun (JP); Takenobu Matsuo, Tosu-shi (JP)

Correspondence Address: CROWELL & MORING LLP, INTELLECTUAL PROPERTY GROUP, P.O. BOX 14300, WASHINGTON, DC, 20044-4300, US

(21) Appl. No.: 10/466,089

(22) PCT Filed: Feb. 27, 2002
(86) PCT No.: PCT/JP02/01786

(30) Foreign Application Priority Data
Mar. 5, 2001 (JP) 2001-60320

(51) Int. Cl. H01L 21/31

(52) U.S. Cl. 438/758

(57) ABSTRACT

A plating system includes a housing forming an outer face thereof. The housing is composed of a frame and a plurality of panels fitted into the frame. Heat contraction is utilized to cover the frame and the panels with synthetic resin films.

### TECHNICAL FIELD

The present invention relates to a fluid treatment system that applies fluid treatment to substrates such as semiconductor wafers.

### BACKGROUND ART

As an apparatus that forms metal layers on the surfaces of substrates such as semiconductor wafers (hereinafter, simply referred to as ‘wafers’), for example, a physical vapor deposition apparatus (a PVD apparatus) that forms metal layers in vapor phase has been conventionally used.

However, with the recent improvement in the degree of integration of semiconductor devices, the use of a plating unit that forms metal layers in liquid phase is becoming on the mainstream in light of the problem of an embedding property.

In general, such a plating unit is often incorporated in a plating system for use. Besides the plating unit, a washing unit that washes a plated surface with a pure water or a chemical solution after the surface to be plated of a wafer is plated, and a drying unit that dries the wafer after the plating on the wafer is washed in this washing unit are disposed in the plating system. Since these processing units are disposed in the plating system, a series of processes involved in plating is continuously performed.

A housing of the plating system as described above is generally formed of metal such as iron. Forming the housing of metal, however, has a problem of causing the corrosion of the housing due to mist of a plating solution which is discharged from the plating unit when the wafer is carried therein/therefrom.

In order to solve this problem of the corrosion of the housing, coating the metal housing with synthetic resin or covering the metal housing with synthetic resin film has been proposed.

Coating the metal housing with the synthetic resin, however, has such a problem that the corrosion of the housing cannot be effectively prevented since the housing cannot be maintained airtight due to a porous property of the coating. It has another problem of causing wafer contamination since a solvent and materials contained in a coating compound evaporate to scatter in a clean room. There is still another problem of causing cost increase since pretreatment such as a blast process is required because the state of a base is important in coating.

FIG. 13 is a vertical sectional view schematically showing a part of a housing covered with a synthetic resin film.

In order to cover a metal housing with a synthetic resin film, a film 101 is made to cover a housing 102 from two directions and end portions thereof are welded together, as shown in FIG. 13.

However, it is difficult to maintain the housing 102 airtight in such welding. To be more specific, there is a problem of the corrosion of the housing 102 since, at the time of this welding, a hole 103 is formed due to insufficient welding and mist of a plating solution enters from this hole 103. Further, since the housing 102 is simply covered with the film 101, the housing 102 cannot be maintained airtight, and thus a space 104 is made between the film 101 and the housing 102. As a result, ions enter the space 104 to cause the problem that the housing 102 is corroded at a portion thereof in contact with the space 104. Moreover, for example, when two pipes different in diameter are welded together to form a part of the housing, there is a problem of the corrosion of the housing since simple covering with the film causes a space to be made in a welded portion due to the change in diameter in the welded portion.

### DISCLOSURE OF THE INVENTION

The present invention is made in order to solve the conventional problems stated above, and it is an object of the present invention to provide a fluid treatment system in which a housing can be maintained airtight and the corrosion of the housing can be prevented.

A fluid treatment system according to an aspect of the present invention is characterized in that it includes: a fluid treatment unit configured to apply fluid treatment to a substrate; and a housing which houses the fluid treatment unit, the housing being at least partly covered with a synthetic resin film through heat contraction.

As the substrate, for example, a wafer or an LCD glass substrate for liquid crystal is usable. The fluid treatment unit is not limited to any specific one as long as it is a unit capable of applying treatment to a substrate using a fluid. An example of such a fluid treatment unit is a plating unit. The housing can be formed, for example, of a frame and a panel, or only of a panel.

Since the fluid treatment system according to the aspect of the present invention has the housing which houses the fluid treatment unit, the housing being at least partly covered with the synthetic resin film through heat contraction, it is possible to maintain the housing airtight to prevent the corrosion of the housing.

The housing in the abovementioned fluid treatment system preferably has a panel in a substantially planar shape at least partly covered with a synthetic resin film through heat contraction. Since such a panel is provided, the corrosion of the panel can be prevented at a part thereof covered with the synthetic resin film.

The housing of the abovementioned fluid treatment system preferably has a frame at least partly covered with a synthetic resin film through heat contraction. Since such a frame is provided, the corrosion of the frame can be prevented at a part thereof covered with the synthetic resin film.

A fluid treatment system according to another aspect of the present invention is characterized in that it includes: a fluid treatment unit configured to apply fluid treatment to a substrate; and a housing which houses the fluid treatment unit, the housing being at least partly covered with a synthetic resin film through lamination.

Since the fluid treatment system according to the aspect of the present invention has the housing which houses the fluid treatment unit, the housing being at least partly covered with the synthetic resin film through lamination, it is possible to maintain the housing airtight to prevent the corrosion of the housing.

The housing in the abovementioned fluid treatment system preferably has a panel in a substantially planar shape at least partly covered with a synthetic resin film through lamination. Since such a panel is provided, the corrosion of the panel can be prevented at a part thereof covered with the synthetic resin film.

The housing of the abovementioned fluid treatment system preferably has a frame at least partly covered with a synthetic resin film through lamination. Since such a frame is provided, the corrosion of the frame can be prevented at a part thereof covered with the synthetic resin film.

The synthetic resin film in the abovementioned fluid treatment system is formed of at least any one of polyetheretherketone, polycarbonate, polyethylene, polyethylene terephthalate, and polypropylene. The use of such synthetic resin makes it possible to provide a synthetic resin film excellent in fluid resistance, workability, strength, and so on.

### BRIEF DESCRIPTION OF DRAWINGS

FIG. 1 is a perspective view schematically showing a plating system according to an embodiment, which includes a fragmentary enlarged view.

FIG. 2 is a see-through perspective view schematically showing the plating system according to the embodiment.

FIG. 3 is a plane view schematically showing the plating system according to the embodiment.

FIG. 4 is a see-through plane view schematically showing the plating system according to the embodiment.

FIG. 5 is a front view schematically showing the plating system according to the embodiment.

FIG. 6 is a see-through front view schematically showing the plating system according to the embodiment.

FIG. 7 is a side view schematically showing the plating system according to the embodiment.

FIG. 8 is a see-through side view schematically showing the plating system according to the embodiment.

FIG. 9 is a vertical sectional view schematically showing a plating unit according to the embodiment, which includes a fragmentary enlarged view.

FIG. 10 is a plane view schematically showing the plating unit according to the embodiment.

FIG. 11 is a flowchart showing the flow in the entire plating system according to the embodiment.

FIG. 12 is a flowchart showing the flow of plating performed in the plating unit according to the embodiment.

FIG. 13 is a vertical sectional view schematically showing the state in which a housing according to a conventional example is covered with a synthetic resin film.

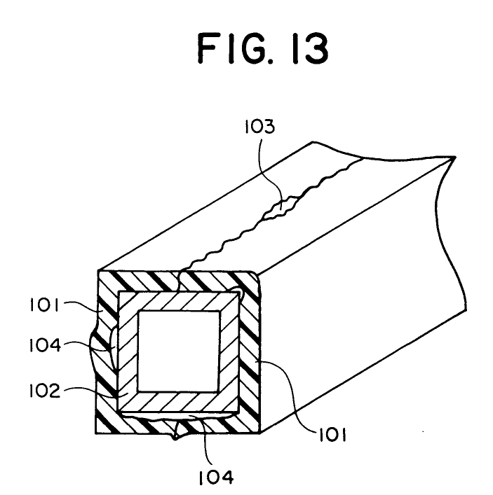

### BEST MODE FOR CARRYING OUT THE INVENTION

Hereinafter, a plating system according to an embodiment of the present invention will be explained.

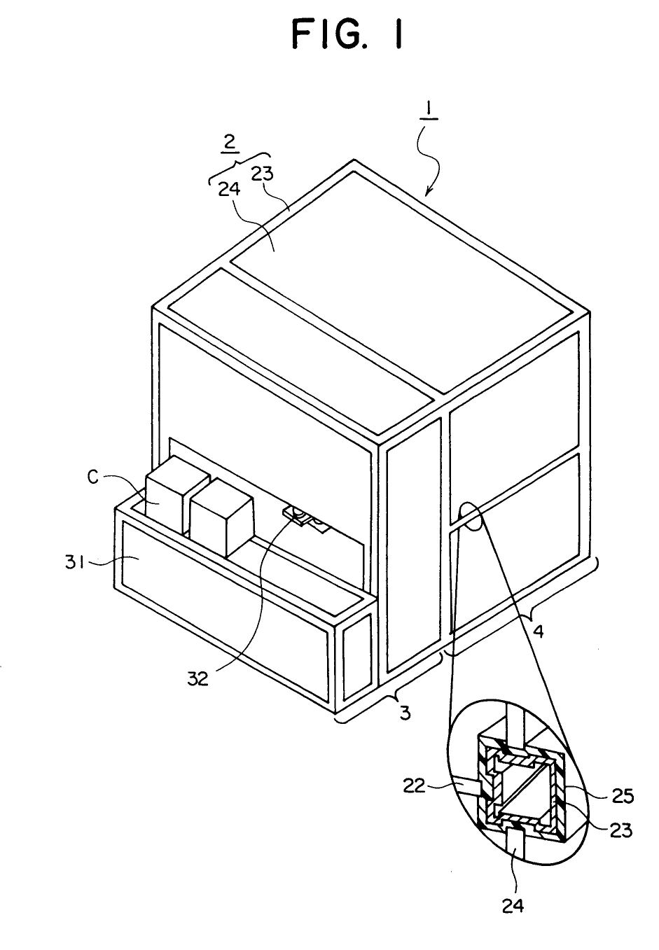

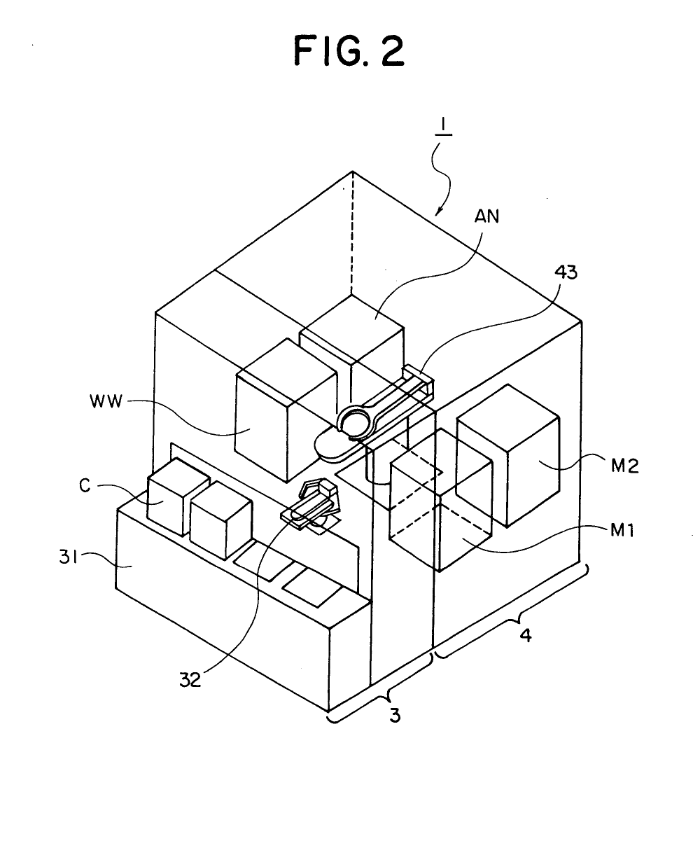

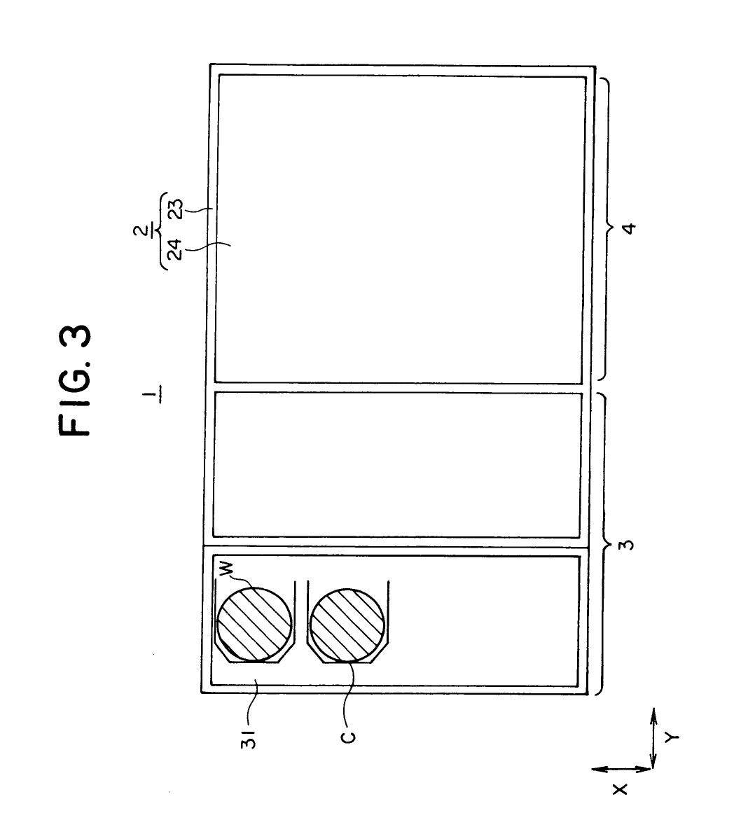

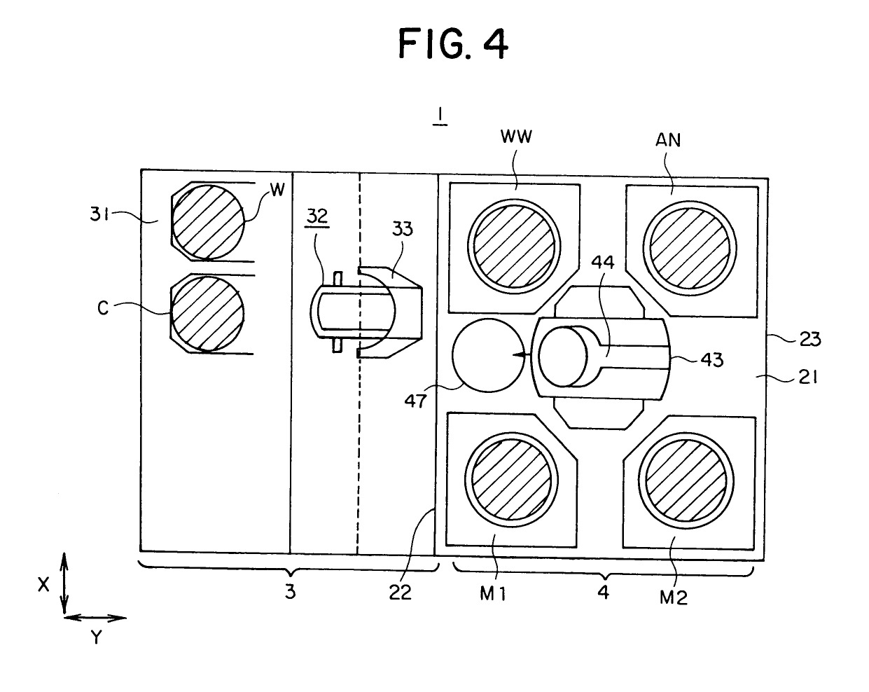

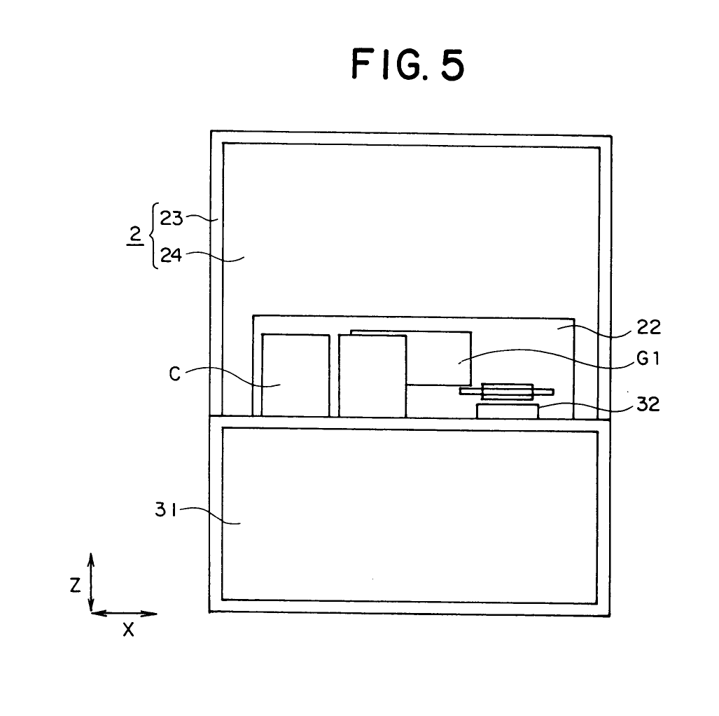

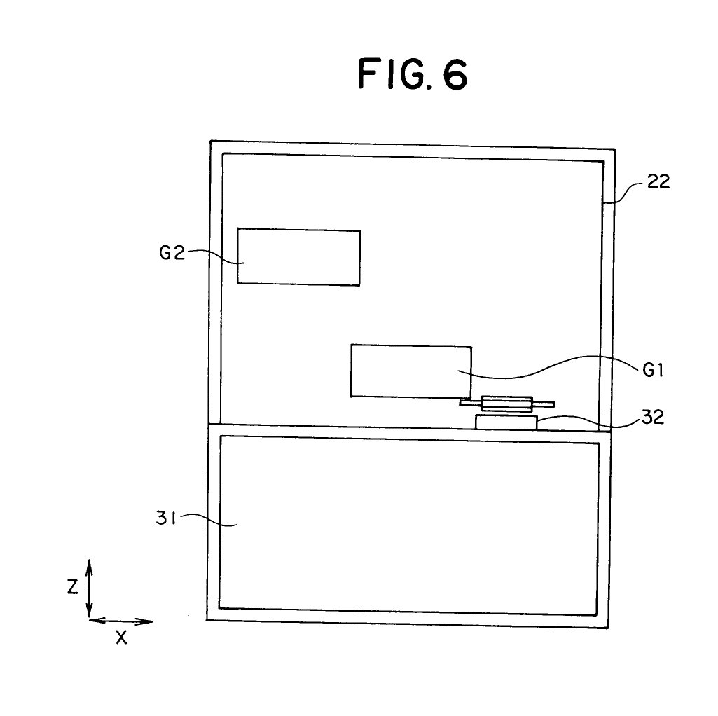

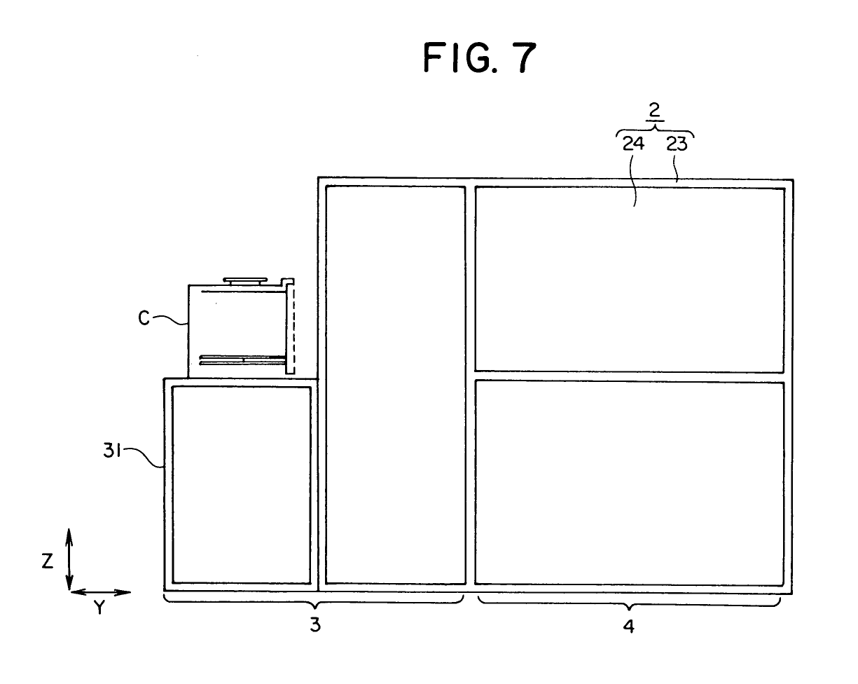

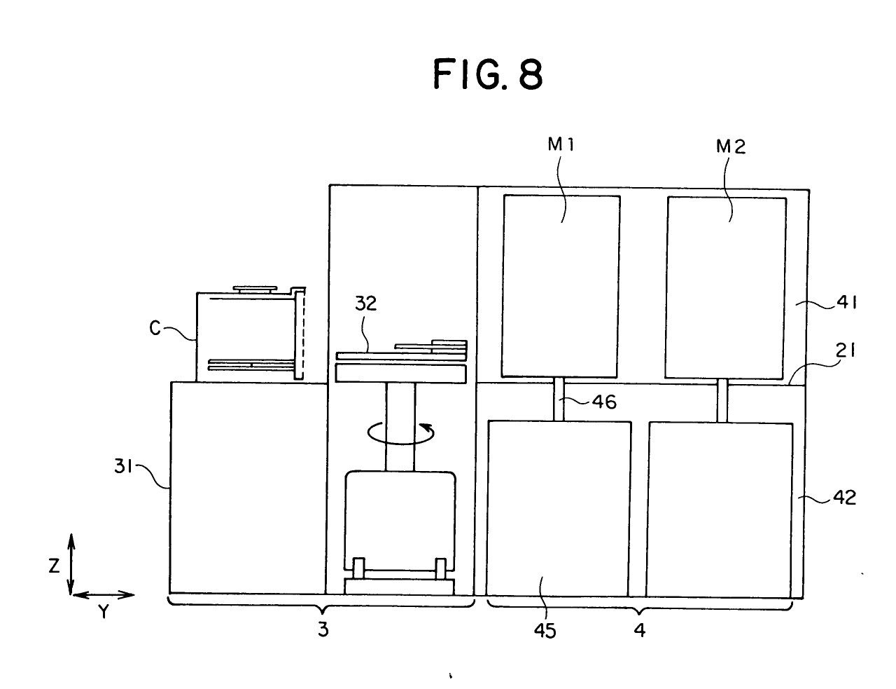

FIG. 1 is a perspective view schematically showing the plating system according to this embodiment, which includes a fragmentary enlarged view, and FIG. 2 is a see-through perspective view schematically showing the plating system according to this embodiment. FIG. 3 and FIG. 4 are a plane view and a see-through plane view schematically showing the plating system according to this embodiment. FIG. 5 and FIG. 6 are a front view and a see-through front view schematically showing the plating system according to this embodiment. FIG. 7 and FIG. 8 are a side view and a see-through side view schematically showing the plating system according to this embodiment.

As shown in FIG. 1 to FIG. 8, a plating system 1 has a housing 2 constituting an outer face of the plating system 1. The inside of the housing 2 is divided by a partition board 22 of the housing 2, which will be described later, into a carrier station 3 that transfers wafers W to/from carrier cassettes C housing the wafers W from/to a later-described process station 4, and the process station 4 that processes the wafers W.

The carrier station 3 is composed of a mounting table 31 to mount the carrier cassettes C thereon and a sub arm 32 that takes out the wafer W from the carrier cassette C mounted on the mounting table 31 and sets the wafer W into the carrier cassette C.

In the carrier cassette C, a plurality of, for example, 25 wafers W are housed, being kept horizontal at equal intervals. On the mounting table 31, for example, four carrier cassettes C are arranged in an X direction.

The sub arm 32 is configured to move on a rail laid in an X direction and to ascend/descend in a Z direction. The sub arm 32 is also configured to rotate on a horizontal plane.

The sub arm 32 has an extendable/contractible wafer holding member 33. The wafer holding member 33 extends/contracts to take out an unprocessed wafer W from the carrier cassette C or to set a processed wafer W into the carrier cassette C. Note that the sub arm 32 transfers the wafer W also to/from the process station 4.

The sub arm 32 is preferably so structured that its body itself is formed of a synthetic resin or its body is made of metal and covered airtightly with a synthetic resin film.

The process station 4 is vertically divided into two tiers by a dividing board 21 of the housing 2. Specifically, the process station 4 is divided into a process section 41 positioned on an upper tier and a treatment solution supply section 42 positioned on a lower tier.

In the process section 41, for example, a plating unit M1 and a washing unit WW are disposed on a side near the carrier station 2. Further, on a side distant from the carrier station 2, for example, a plating unit M2 having a plating solution with a different composition from that of a plating solution in the plating unit M1 and an annealing unit AN are disposed.

In the process section 41, a main arm 43 to carry the wafer W into each of the processing units or to carry the wafer W out of each of the processing units is disposed at the center of the aforesaid four processing units.

The main arm 43 is so structured to ascend/descend and also to rotate on a substantially horizontal plane. The main arm 43 is preferably so structured that its body itself is formed of synthetic resin or its body is made of metal and covered airtightly with a synthetic resin film.

The main arm 43 has two upper and lower wafer holding members 44 extendable/contractible on a substantially horizontal plane. The wafer holding members 44 extend/contract to carry the wafer W to/from each of the processing units.

The main arm 43 has a mechanism for turning the wafer W held thereby upside down. Since this mechanism is provided, the wafer W can be turned upside down while the wafer W is carried from one processing unit to another processing unit. Note that the function of turning the wafer W upside down is not a function essential to the main arm 43.

In the treatment solution supply section 42, tanks 45 in each of which, for example, a plating solution or a wash is stored, are provided. The plating unit M1, the plating unit M2, or the washing unit WW is connected to each of the tanks 45 via a pipe 46. The plating solution or the wash is pumped up from the tank 45 with a not-shown pump to be supplied to the plating unit M1, the plating unit M2, or the washing unit WW.

The partition board 22 is provided between the carrier station 3 and the process station 4. The partition board 22 has in two places thereof opening portions G1 and G2 which can be opened/closed.

The opening portion G1 is used when the unprocessed wafer W is carried into the process station 4. When the wafer W is to be carried in, the opening portion G1 is opened and the sub arm 32 holding the unprocessed wafer W carries the wafer W into the process station 4. Incidentally, the sub arm 32 places the wafer W on an intermediary mounting table 47 provided in the process station 4.

The opening portion G2 is used when the processed wafer W is carried out of the process station 4. When the wafer W is to be carried out, the opening portion G2 is opened and the sub arm 32 extends into the wet washing unit WW to hold the washed wafer W and carries out the wafer W from the process station 4.

Hereinafter, the plating unit M1 disposed in the process station 4 will be explained in detail.

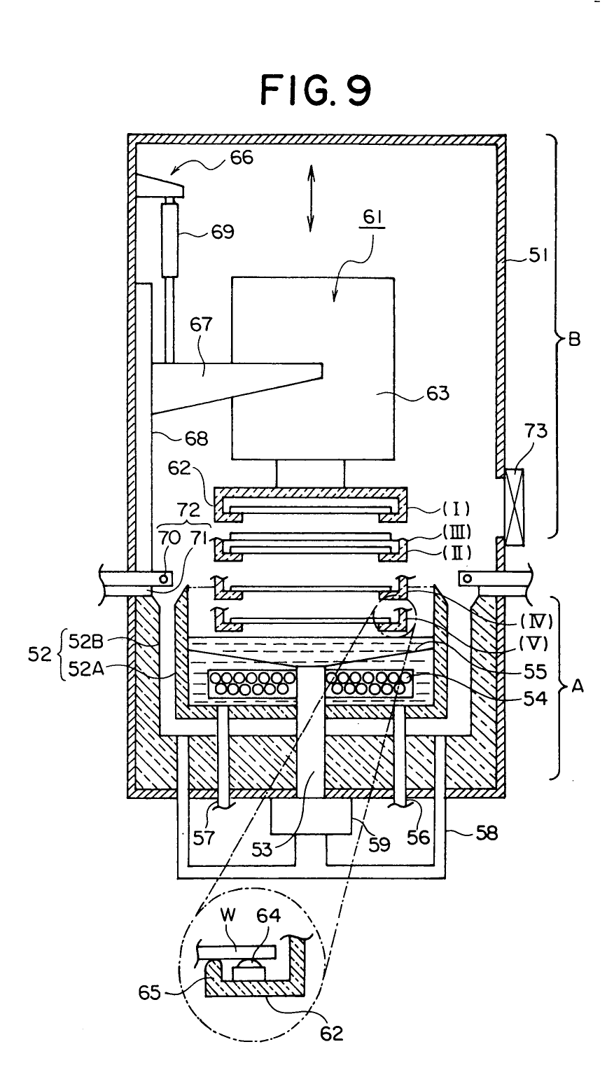

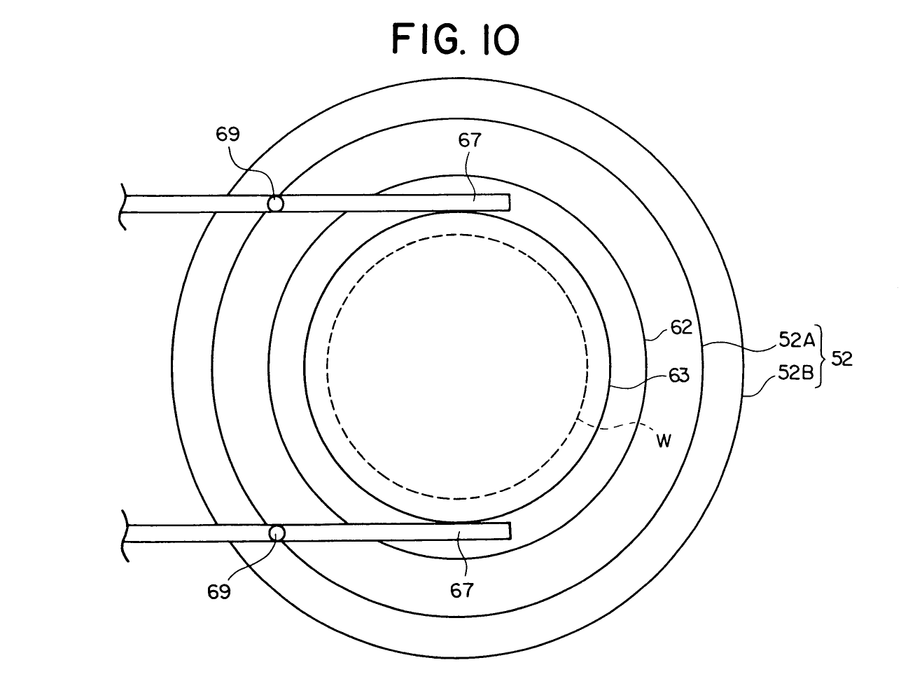

FIG. 9 is a vertical sectional view schematically showing the plating unit M1 according to this embodiment, which includes a fragmentary enlarged view, and FIG. 10 is a plane view schematically showing the plating unit M1 according to this embodiment.

As shown in FIG. 9 and FIG. 10, the plating unit M1 has a case 51. The case 51 is preferably formed of synthetic resin or of metal covered airtightly with a synthetic resin film.

The inside of the case 51 is vertically divided into two tiers, namely, a first process section A positioned on a lower tier and a second process section B positioned on an upper tier.

A plating solution tank 52 is disposed inside the first process section A. The plating solution tank 52 is formed of a dual tank consisting of an inner tank 52A and an outer tank 52B disposed outside the inner tank 52A.

The inner tank 52A is formed in a substantially cylindrical shape with a closed bottom. An ejecting pipe 53 that ejects a plating solution from a bottom face side to an upper face of the inner tank 52A protrudes into the inner tank 52A. An anode electrode 54 in a substantially disk shape that is formed by, for example, the assembly of a plurality of copper balls is provided to surround the ejecting pipe 53.

A diaphragm 55 vertically partitioning the inner tank 52A is disposed above the anode electrode 54 between an outer periphery of an end portion of the ejecting pipe 53 and the inner tank 52A. The diaphragm 55 is structured so as to transmit ions and not to transmit impurities generated when the anode electrode 54 dissolves and bubbles, for example, oxygen and hydrogen generated during plating processes.

The plating solution is supplied from the ejecting pipe 53 to an upper side of the inner tank 52A partitioned by the diaphragm 55 (hereinafter, referred to as an ‘upper side of the inner tank’). The plating solution is supplied from a circulation pipe 56, which will be described later, to a lower side of the inner tank 52A partitioned by the diaphragm 55 (hereinafter, referred to as a ‘lower side of the inner tank’).

Circulation pipes 56 and 57 are provided at positions deviated from the center of the bottom face of the inner tank 52A. A not-shown pump is disposed between the circulation pipes 56 and 57. The operation of the not-shown pump causes the plating solution to circulate between the circulation pipes 56 and 57.

The outer tank 52B is formed in a substantially cylindrical shape with a closed bottom similarly to the inner tank 52A. A pipe 58 is connected to the bottom portion of the outer tank 52B, and a pump 59 is provided between the pipe 58 and the ejecting pipe 53. When the pump 59 is operated, the plating solution which has been stored in the outer tank 52B after overflowing from the inner tank 52A is supplied again to the upper side of the inner tank 52A.

The tank 45 in which the plating solution is stored is connected to the pipe 58 via the pipe 46.

In the second process section B, a driver 61 to hold the wafer W is provided directly above the center of the plating tank 52. The driver 61 is composed of a holder 62 to hold the wafer W and a motor 63 to rotate the wafer W together with the holder 62 on a substantially horizontal plane.

As shown in the fragmentary enlarged view in FIG. 9, convex contacts 64 through which a voltage is applied to the wafer W are arranged on an inner side of a bottom face of the holder 62 at positions equally dividing the bottom face to 248 portions.

Each of the contacts 64 is electrically connected to a not-shown external power supply via a lead wire. The wafer W having a seed layer formed on a surface to be plated thereof is mounted on the contacts 64. Consequently, the voltage applied to the contacts 64 is also applied to the surface to be plated of the wafer W.

A seal member 65 is provided on the inner side of the bottom face of the holder 62. When the wafer W is held, the seal member 65 is pressed via the wafer W. Since the seal member 65 is pressed, the plating solution is prevented from entering the inner side of the holder 62.

A hoisting/lowering mechanism 66 to hoist/lower the driver 61 relatively to the plating solution tank 52 is attached to the motor 63. The hoisting/lowering mechanism 66 is mainly composed of a support beam 67 attached to an outer case of the motor 63 and supporting the driver 61, a guide rail 68 attached to an inner wall of the case 51, and a cylinder 69 extendable/contractible in a vertical direction that hoists/lowers the support beam 67 along the guide rail 68. When the cylinder 69 is driven, the driver 61 supported by the support beam 67 moves up/down along the guide rail 68 to hoist/lower the wafer W.

Specifically, with the hoisting/lowering mechanism 66, the wafer W ascends/descends to positions different in height, that is, a transfer position (I) for transfer, a wafer washing position (II) for washing the plated surface of the wafer W with a wash, for example, a pure water, a contact washing position (III) for washing the contacts 64 with a wash, for example, a pure water, a spin dry position (IV) for spin drying for removing an unnecessary plating solution and moisture, and a plating position (V) for plating the wafer W. The transfer position (I), the wafer washing position (II), and the contact washing position (III) are higher than the level of the plating solution when the inner tank 52A is filled with the plating solution, and the spin dry position (IV) and the plating position (V) are lower than the level of the plating solution.

A separator 72 having a washing nozzle 70 and an exhaust port 71 provided therein is disposed between the first process section A and the second process section B. A through hole is provided at the center of the separator 72 so as to allow the wafer W held by the driver 61 to move between the first process section A and the second process section B.

A gate valve 73 through which the wafer W is carried into/out of the plating unit M1 is provided in a portion corresponding to the border between the first process section A and the second process section B of the case 51.

Next, the housing 2 of the plating system 1 will be explained in detail.

The housing 2 is composed of a frame 23 and a plurality of panels 24 fitted into a space surrounded by the frame 23. The frame 23 and the panels 24 are formed of metal, for example, iron.

The frame 23 is formed in such a manner that pipes having a square sectional shape or pipes having a circular sectional shape are bent and welded together. Incidentally, the square pipes or the circular pipes can be formed by a common method, for example, extrusion.

Each of the panels 24 is formed in a flat plate shape by a common method, for example, rolling. The panels 24 are used as side boards, a top board, a bottom board, a carrier cassette mounting board, the dividing board 21, and the partition board 22 of the plating system 1.

The frame 23 and the panels 24 are covered with films 25 formed of synthetic resin. Here, in this embodiment, the films 25 cover the whole outer periphery of the frame 23 and the whole surfaces of the panels 24 respectively. Heat contraction is utilized to cover the frame 23 and the panels 24 with the films 25. The heat contraction means that the films 25 contract when the films 25 are heated.

In order to cover the frame 23 and the panels 24 through the utilization of the heat contraction, the films 25 are first formed, for example, in a tube shape by a common method such as extrusion. Next, the films 25 formed in the tube shape are made to cover the frame 23 and the panels 24, and thereafter heated by a not-shown heating unit. This heating causes the films 25 to contract so that the frame 23 and the panels 24 are covered with the films 25. Here, an adhesive is not used when the frame 23 and the panels 24 are covered with the films 25 through the heat contraction of the films 25.

Concretely, as the synthetic resin forming the films 25, it is preferable to use at least any one thermoplastic synthetic resin out of, for example, polyethylene (PE), polypropylene (PP), polyvinylidene chloride (PVDC), polyethylene terephthalate (PET), polyphenylene sulfide (PPS), polyetheretherketone (PEEK), liquid crystal polymer (LCP), polysulfone (PSU), polyethersulfone (PES), polyarylate (PAR), polyamideimide (PAI), polyetherimide (PEI), polyimide (PI), polyamide (PA), polyacetal (POM), polybutylene terephthalate (PBT), GF-reinforced polyethylene terephthalate (GF-PET), polycarbonate (PC), polyphenyleneether (PPE), acrylonitrile-butadiene-styrene (ABS), polystyrene (PS), methyl methacrylate (PMMA), and polyvinyl chloride (PVC). The thermoplastic synthetic resin is preferable because it is excellent in plating solution resistance, workability, strength, and so on.

Further, among all of the above, it is more preferable to use at least any one synthetic resin out of polyetheretherketone (PEEK), polycarbonate (PC), polyethylene (PE), polyethylene terephthalate (PET), and polypropylene (PP). These synthetic resins are more preferable because they are more excellent in plating solution resistance, workability, strength, and so on.

Moreover, these synthetic resins do not contain a large volume of additive, for example, plasticizer, fire retardant, and antioxidant. This avoids the situation that a polymer contained in the additive vaporizes to scatter in a clean room, which can prevent the contamination of the wafer W.

The thickness of the films 25 is preferably 0.1 mm or less. The thickness of the films 25 is set to 0.1 mm or less because the thickness of more than 0.1 mm makes the covering difficult and causes cost increase.

In this embodiment, since the heat contraction is utilized to cover the frame 23 and the panels 24 with the films 25, the frame 23 and the panels 24 can be maintained airtight. As a result, the corrosion of the housing 2, more particularly, the corrosion of the frame 23 and the panels 24 constituting the housing 2 can be prevented.

To be more specific, when the heat contraction of the films 25 occurs, the films 25 come in close contact with the surfaces of the frame 23 and the panels 24, as shown in the fragmentary enlarged view in FIG. 1. Owing to the close contact of the films 25, spaces are not easily formed between the films 25 and the frame 23 or between the films 25 and the panels 24. As a result, the frame 23 and the panels 24 are not easily corroded even when the mist of the plating solution generated in the plating unit M1 is discharged when the wafer W is carried in/out to scatter in the housing 2.

Since the heat contraction of the films 25 is utilized, the frame 23 and the panels 24 can be covered easily. Moreover, the films 25 need not be welded together, and therefore, no hole formed due to insufficient welding occurs.

Since the heat contraction of the films 25 is utilized, it is possible to cover the frame 23 and the panels 24 regardless of bases. As a result, no pretreatment such as a blast process is required, which can realize cost reduction.

Since the heat contraction of the films 25 is utilized, even when, for example, two pipes different in diameter are welded together to form the frame 23, the film 25 comes in close contact with a welded portion where the diameter changes. As a result, a space does not easily occur in the welded portion.

Here, since two pipes are heated and joined together at each welded portion of the frame 23, the welded portion of the frame 23, in which the metal composition is changed, is especially subject to corrosion. In this embodiment, however, since the close contact state of the films 25 is obtained through the heat contraction, it is possible to maintain the welded portions of the frame 23 airtight to prevent corrosion.

Further, since no adhesive is used when the frame 23 and the panels 24 are covered, it is possible to reduce the total thickness of the film 25 and the frame 23 or the film 25 and the panel 24 and to realize cost reduction as well.

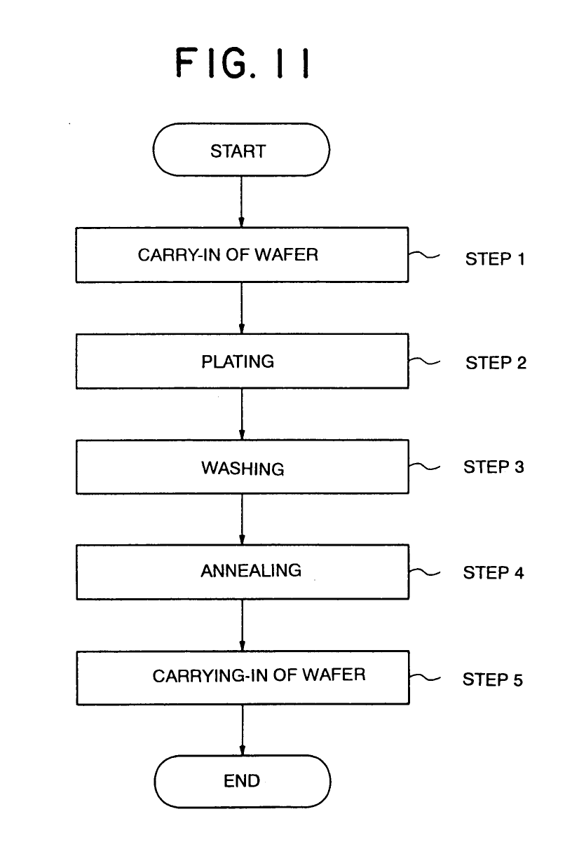

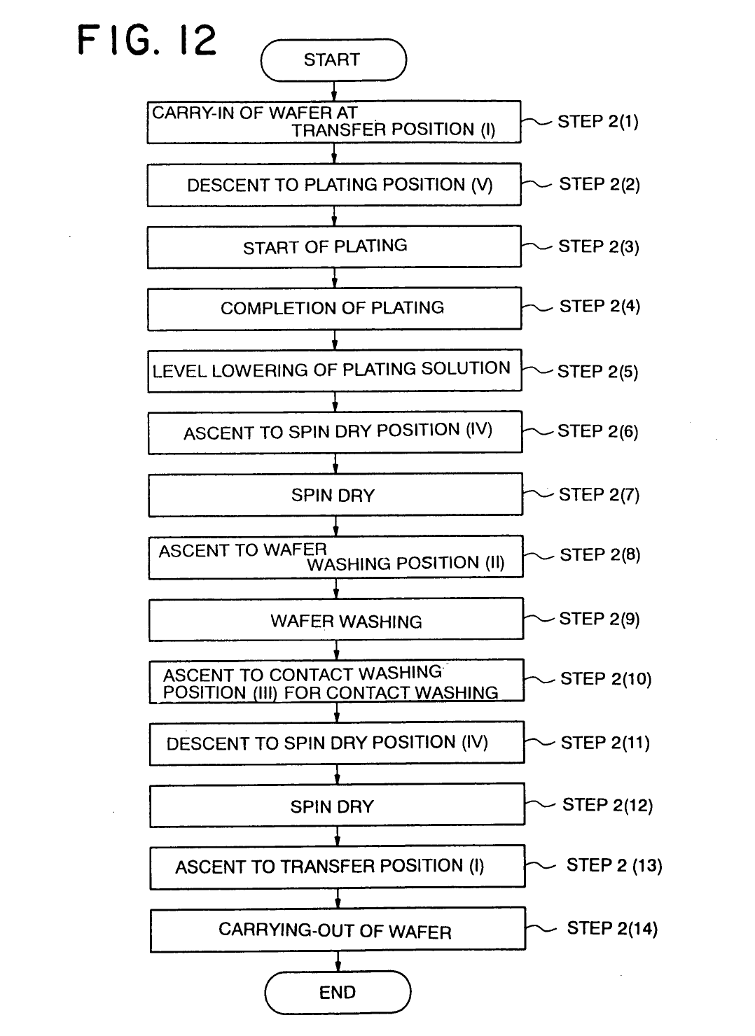

Hereinafter, the process performed in the plating system 1 will be explained. FIG. 11 is a flowchart showing the flow of the entire plating system 1 according to this embodiment, and FIG. 12 is a flowchart showing the flow of plating performed in the plating unit M1 according to this embodiment.

The carrier cassette C housing one lot of the wafers W, for example, 25 wafers W is mounted on the mounting table 31 of the carrier station 3 (Step 1).

When the carrier cassette C is mounted on the mounting table 31, the sub arm 32 moves to the front of the carrier cassette C to take an unprocessed wafer W out of the carrier cassette C mounted on the mounting table 31.

Thereafter, the sub arm 32 rotates, and at the same time, the wafer holding member 33 holding the wafer W extends to temporarily mount the wafer W on the intermediary mounting table 47 via the opening portion G1.

When the wafer W is mounted on the intermediary mounting table 47, the wafer holding member 44 extends to receive the wafer W on the intermediary mounting table 47. After the wafer holding member 44 receives the wafer W, the main arm 43 rotates, and at the same time, turns the wafer W upside down.

Thereafter, the wafer holding member 44 extends to carry the wafer W into the plating unit M1.

When the wafer W is carried into the plating unit M1, plating is started and the surface to be plated of the wafer W is plated according to the flow shown in FIG. 12 (Step 2), (Step 2(1) to Step 2(14)). Here, when the wafer W is carried into the plating unit M1 or carried out of the plating unit M1, the gate valve 73 is opened, so that the mist of the plating solution in the plating unit M1 scatters in the plating system 1. In this embodiment, however, since the housing 4 is covered airtightly with the synthetic resin films 25, the corrosion of the frame 23 and the panels 24 can be prevented even when the mist of the plating solution scatters in the plating system 1.

After the plating is finished in the plating unit M1, the wafer W held by the wafer holding member 44 is carried into the plating unit M2, if necessary, in which the plating solution different in composition is stored, and the wafer W is plated therein.

After a series of the plating processes is finished, the wafer holding member 44 holding the wafer W carries the wafer W into the washing unit WW, where the plated surface and the rear surface of the wafer W are washed (Step 3).

After the plated surface and the rear surface of the wafer W are washed, the wafer W is annealed in the annealing unit AN (Step 4).

After the wafer W is annealed, the main arm 43 receives the wafer W again to deliver the wafer W to the sub arm 32 via the washing unit WW. Next, the wafer holding member 33 extends to return the wafer W having subjected to a series of the processes into the carrier cassette C. Thereafter, the wafer W is carried to another treatment system performing subsequent treatment (Step 5).

It should be noted that the present invention is not limited to the described contents of the above embodiment, and any appropriate change in the structure, the material, the arrangement of the members, and so on may be made therein without departing from the spirit of the present invention. For example, the frame 23 and the panels 24, though formed of metal in the above-described embodiment, need not be formed of metal.

In the above-described embodiment, the whole periphery of the frame 23 and the whole surfaces of the panels 24 are covered with the films 25, but the films 25 may cover only parts of the frame 23 and the panels 24, that is, portions especially subject to corrosion.

In the above-described embodiment, the heat contraction is utilized to cover the frame 23 and the panels 24 with the films 25, but lamination may be utilized to cover the frame 23 and the panels 24 with the films 25. Here, the lamination means to paste a synthetic resin film onto a base material such as metal with an adhesive. The utilization of the lamination makes it possible to cover the frame 23 and the panels 24 more airtightly.

The lamination includes, for example, dry lamination and hot melt lamination.

The dry lamination is a method in which a film is dried after being coated with an adhesive, and thereafter, bonded by thermal contact. As the adhesive in this case, usable are, for example, a vinyl-based resin, an acryl-based resin, a polyamide-based resin, an epoxy-based resin, a rubber-based resin, and a urethane-based resin.

The hot melt lamination is a method in which a synthetic resin film dissolved by heating is coated with an adhesive and is pasted onto a base material as it is. For example, the adhesive including EVA, polyester, styrene elastomer or polyamide as a base polymer can be used in this case.

In the above-described embodiment, the frame 23 and the panels 24 which are made of metal are covered with the synthetic resin films 25, but the frame 23 and the panels 24 themselves may be formed of synthetic resin by extrusion or the like. Forming the frame 23 and the panels 24 themselves of synthetic resin can make the frame 23 and the panels 24 free of corrosion. This case is not limited to forming the whole frame 23 and the whole panels 24 of the synthetic resin, but parts of the frame 23 and the panels 24, that is, only portions especially subject to corrosion may be formed of synthetic resin. Further, when the frame 23 and 24 are formed, covering them with the films 25 and forming them of synthetic resin may be combined.

### INDUSTRIAL APPLICABILITY

A fluid treatment system according to the present invention is usable in the semiconductor manufacturing industry.

What is claimed is:

1. A fluid treatment system, comprising:
a fluid treatment unit configured to apply fluid treatment to a substrate; and
a housing which houses said fluid treatment unit, the housing being at least partly covered with a synthetic resin film through heat contraction.

2. A fluid treatment system as set forth in claim 1, wherein said housing has a panel in a substantially planar shape at least partly covered with a synthetic resin film through heat contraction.

3. A fluid treatment system as set forth in claim 1, wherein said housing has a frame at least partly covered with a synthetic resin film through heat contraction.

4. A fluid treatment system as set forth in claim 1, wherein said synthetic resin film is formed of at least any one of polyetheretherketone, polycarbonate, polyethylene, polyethylene terephthalate, and polypropylene.

5. A fluid treatment system, comprising:
a fluid treatment unit configured to apply fluid treatment to a substrate; and
a housing which houses said fluid treatment unit, the housing being at least partly covered with a synthetic resin film through lamination.

6. A fluid treatment system as set forth in claim 5, wherein said housing has a panel in a substantially planar shape at least partly covered with a synthetic resin film through lamination.

7. A fluid treatment system as set forth in claim 5, wherein said housing has a frame at least partly covered with a synthetic resin film through lamination.

8. A fluid treatment system as set forth in claim 5, wherein said synthetic resin film is formed of at least any one of polyetheretherketone, polycarbonate, polyethylene, polyethylene terephthalate, and polypropylene.
